(19) United States
(12) Patent Application Publication
(10) Pub. No.: US 2013/0250530 A1
(43) Pub. Date: Sep. 26, 2013

(54) ELECTRONIC DEVICE HAVING SENSOR WINDOW COVER

(71) Applicants: XUE-DONG TANG, Shenzhen City (CN); WEI LIU, Shenzhen City (CN)

(72) Inventors: XUE-DONG TANG, Shenzhen City (CN); WEI LIU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/557,197

(22) Filed: Jul. 24, 2012

(30) Foreign Application Priority Data
Mar. 23, 2012 (CN) 201210079146.0

(51) Int. Cl. H05K 5/02

(52) U.S. Cl. 361/752

(57) ABSTRACT

An electronic device includes a housing, a circuit board received in the housing, a signal receiving unit secured to the circuit board, a sensor window cover secured to the housing and corresponding to the signal receiving unit, and at least one limiting post secured to an inner surface of the housing. The sensor window cover defines at least one limiting hole for receiving the at least one limiting post. The circuit board abuts the sensor detector window to secure the sensor window cover to the housing when the at least one limiting post is received in the at least one limiting hole.

### BACKGROUND

1. Technical Field

The present disclosure relates to electronic devices, and particularly to an electronic device having a sensor window cover.

2. Description of Related Art

Electronic devices, such as DVD players, may include a housing and a sensor window cover secured to the housing. The sensor window cover includes a hook member. The housing defines an area to be covered by the sensor window cover, and includes a latching member arranged adjacent to the area. The latching member corresponds to the hook member and hooks the hook member to secure the sensor window cover to the housing. However, if the sensor window cover is made of brittle materials such as polymethyl methacrylate, the sensor window cover may be broken when being secured to the housing.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the seven views.

FIG. 1 is a partial perspective view of an electronic device having a sensor window cover in accordance with an embodiment.

FIG. 2 is a partially disassembled view of the electronic device of FIG. 1.

FIG. 3 is similar to FIG. 2, but viewed from another aspect.

FIG. 4 is an enlarged view of portion IV in FIG. 3.

FIG. 5 is a perspective view of the sensor window cover in FIG. 1.

FIG. 6 is a partial assembly view of the electronic device of FIG. 2.

FIG. 7 is a partially cut-away view cut away from the electronic device of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

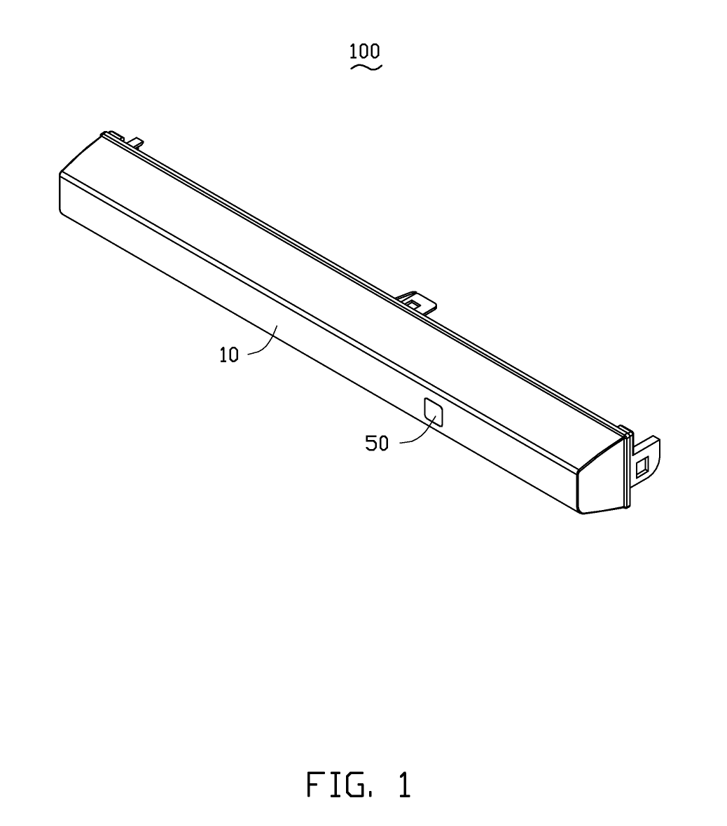

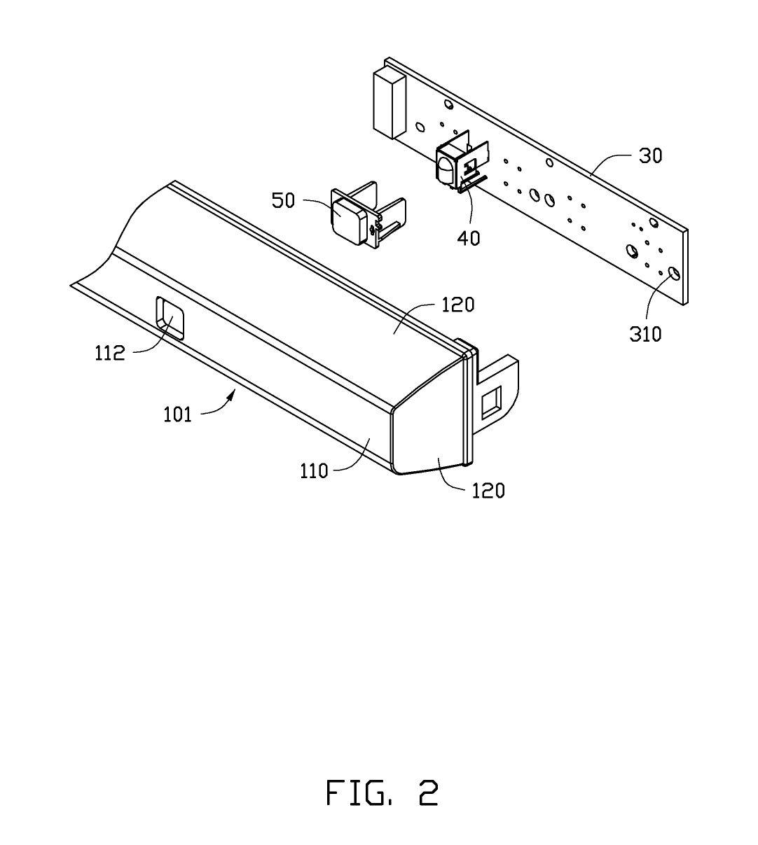

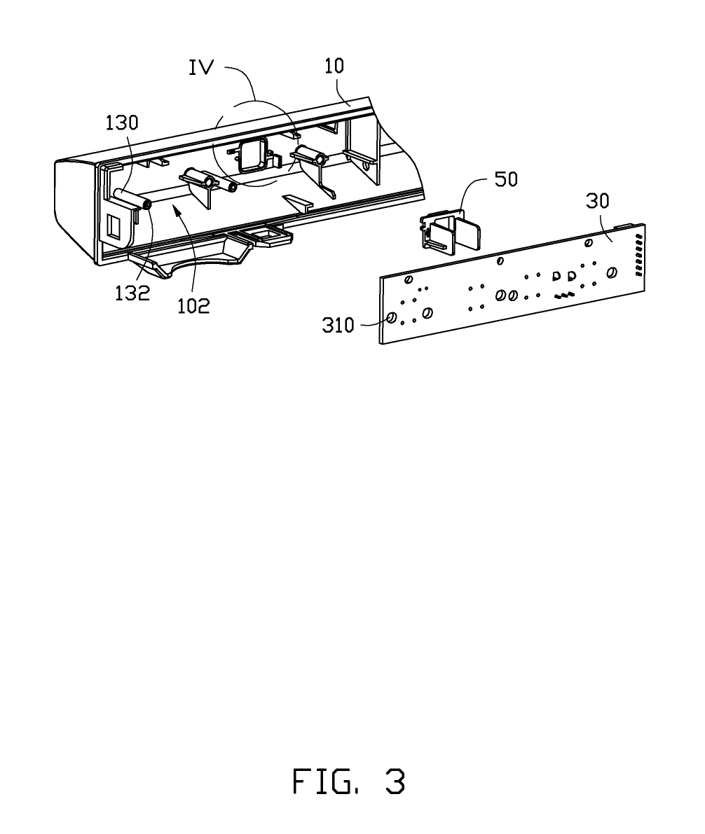

Referring to FIG. 1, an electronic device 100 having a sensor window cover 50 is shown. Referring also to FIGS. 2-3, the electronic device 100 includes a housing 10, a circuit board 30 received in the housing 10, a signal receiving unit 40 arranged on the circuit board 30, and a sensor window cover 50 secured to the housing 10 and corresponding to the signal receiving unit 40.

The housing 10 includes a front case 101 and a rear case (not shown). The front case 101 engages with the rear case to define a receiving space 102 for receiving the circuit board 30, the signal receiving unit 40, and other electronic components (not shown) of the electronic device 100. The front case 101 includes a front wall 110 and a plurality of sidewalls 120 protruding from rims of the front wall 110. The front wall 110 defines an opening 112. The opening 112 is substantially rectangular, and is used for securing the sensor window cover 50. A plurality of fixing posts 130 are secured on an inner surface of the front wall 110. Each fixing post 130 defines a fixing hole 132.

The circuit board 30 is substantially rectangular, and is arranged parallel to the front wall 110. The circuit board 30 defines a plurality of through hole 310 corresponding to the fixing holes 132. Fixing members (such as screws, not shown) extend through the through holes 310 and are further secured to the fixing holes 132, to fix the circuit board 30 to the front case 101. The signal receiving unit 40 is secured to the circuit board 30 and corresponds to the opening 112.

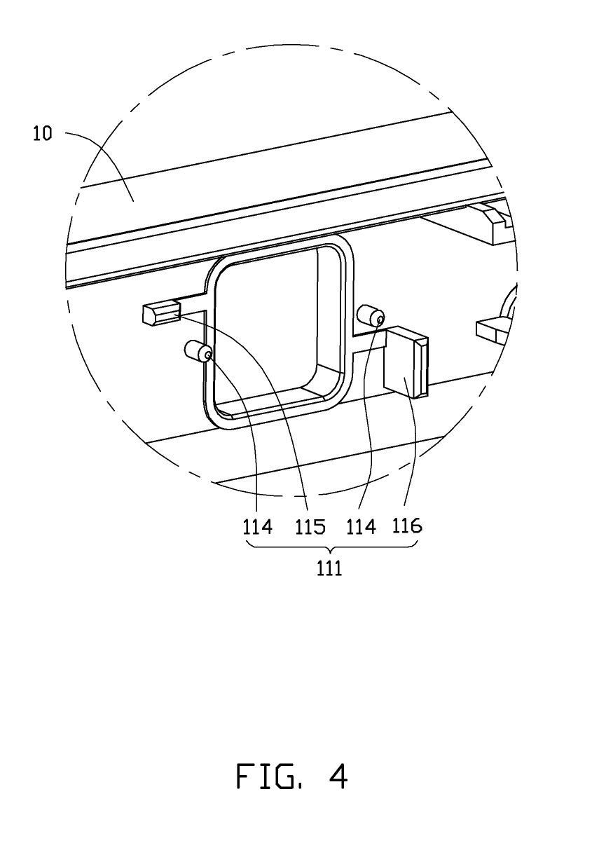

Referring to FIG. 4, a limiting mechanism 111 is secured to an inner surface of the front wall 110. The limiting mechanism 111 includes two limiting posts 114. The limiting posts 114 are perpendicularly arranged on the inner surface of the front wall 110 and are symmetrically arranged on opposite sides of the opening 112. In the embodiment, the limiting posts 114 are aligned in a line (referred herein as the connecting line) extending along the length of the front wall 110. The limiting mechanism 111 further includes a limiting block 115 and a stopping block 116. Longitudinal planes of the limiting block 115 and the stopping block 116 are perpendicular to each other. The limiting block 115 and the stopping block 116 are positioned at opposite sides of the opening 112. The limiting block 115 and the stopping block 116 are arranged at opposite side of the connecting line, with the limiting block 115 parallel to the connecting line and the stopping block 116 perpendicular to the connecting line.

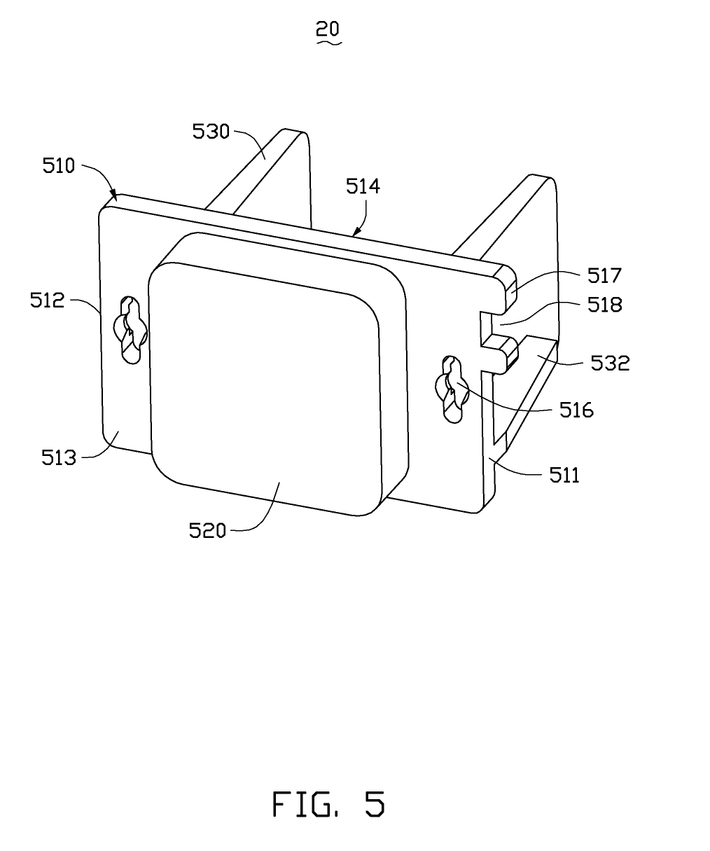

Referring to FIG. 5, the sensor window cover 50 includes a base 510 and a window 520 arranged on the base 510. The base 510 is substantially rectangular and includes a first end 511, and a second end 512 opposite to the first end 511. The length of the base 510 (namely the distance between the first and second ends 511, 512) is slightly less than the distance between an end of the limiting block 115 adjacent to the opening 112 and a plane where the stopping block 116 is aligned. The window 520 is arranged on a front surface 513 of the base 510 and is between the first and second ends 511, 512. The size of the window 520 is slightly less than the size of the opening 112. When viewed from the front surface 513 of the base 510, the window 520 protrudes out of the front surface 513; when viewed from a rear surface 514 of the base 510, the window 520 is recessed in the rear surface 514 of the base 510. In the embodiment, the sensor window cover 50 is made of polymethyl methacrylate.

The base 510 further defines two limiting holes 516. The limiting holes 516 are symmetrically arranged at opposite sides of the window 520. The limiting holes 516 correspond to and receive the limiting posts 114 respectively. Two protruding blocks 517 protrude from the second end 512 of the base 510. The protruding blocks 517 are spaced from each other to define a recess 518. The recess 518 is substantially U-shaped and corresponds to the limiting block 115. The recess 518 is adapted to receive the limiting block 115 when the window 520 is received in the opening 112. The distance between the distal end of the protruding blocks 517 and the window 520 is greater than the distance between the stopping block 116 and an edge of the opening 112 adjacent to the stopping block 116.

Furthermore, two supporting plates 530 are perpendicularly secured to the rear surface 514 of the base 510. The supporting plates 530 are parallel to each other and are arranged at opposite sides of the opening 112. In the embodiment, each supporting plate 530 is arranged between one of the limiting hole 516 and the opening 112. Two ribs 532 are secured to the rear surface 514 of the base 510. Each rib 532 connects with a side of one supporting plate 530 opposite to the other supporting plate 530, to enhance the stiffness of the supporting plates 530.

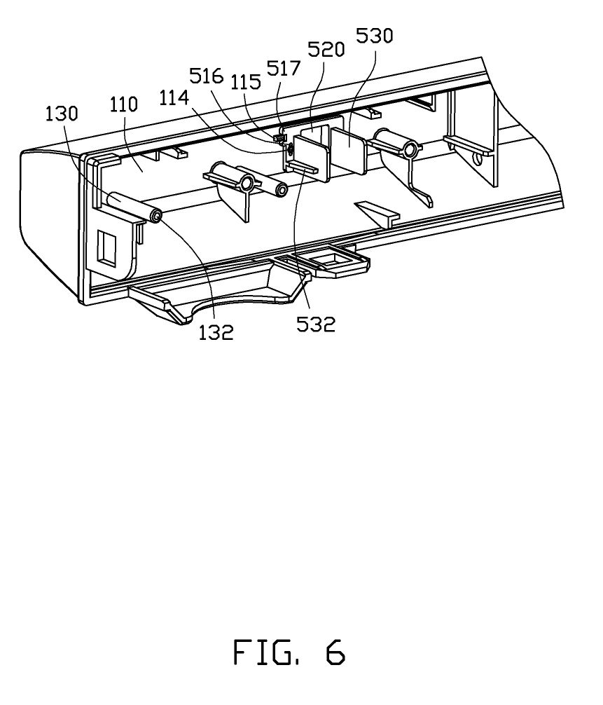

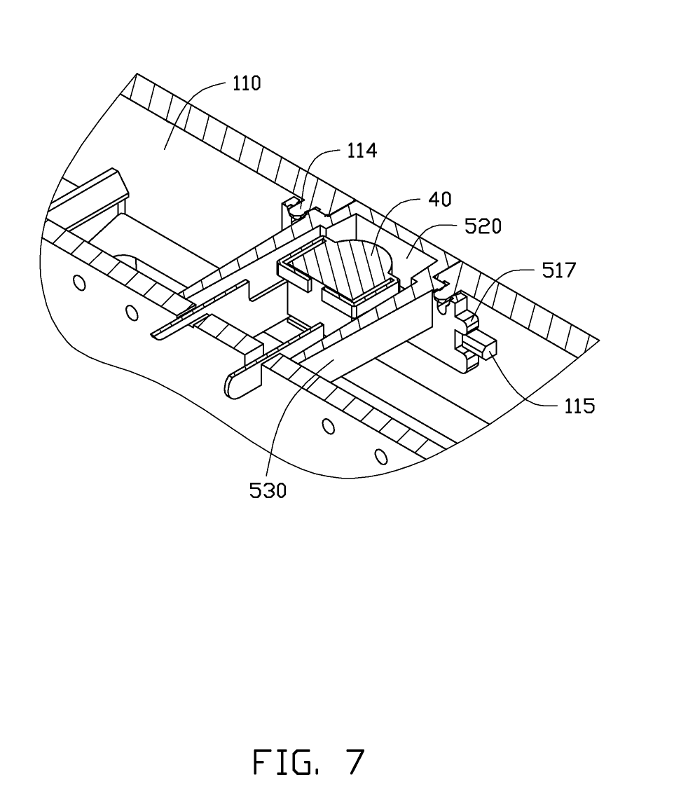

Referring to FIGS. 6-7, in assembly, the window 520 is received in the opening 112 with the limiting block 115 being received in the recess 518 and the limiting posts 114 being received in the limiting holes 516. The circuit board 30 is secured to the fixing posts of the front wall 110 and further abuts ends of the supporting plates 530 away from the base 510 to prevent the sensor window cover 50 from disengaging with the front case 101.

After assembly, the window 520 is received in the opening 112 and the limiting posts 114 is received in the limiting holes 516, thus, the sensor window cover 50 is prevented from moving in a direction parallel to the front wall 110. At the same time, the circuit board 30 abuts ends of the supporting plates 530 away from the base 510, thus, the sensor window cover 50 is prevented from moving in a direction perpendicular to the front wall 110. As a result, the sensor window cover 50 is steadily secured to the front case 101.

Furthermore, because the limiting block 115 is received in the recess 518 and the stopping block 116 abuts the second end 512 of the base 510, the sensor window cover 50 is further prevented from moving a direction parallel to the front wall 110. Because the distance between the distal end of the protruding blocks 517 and the window 520 is greater than the distance between the stopping block 116 and the edge of the opening 112 adjacent to the stopping block 116, the stopping block 116 stops the protruding blocks 517 from engaging therewith to prevent the sensor window cover 50 from being reversely installed.

It is to be understood, even though information as to, and advantages of, the present embodiments have been set forth in the foregoing description, together with details of the structures and functions of the present embodiments, the disclosure is illustrative only; and that changes may be made in detail, especially in the matters of shape, size, and arrangement of parts within the principles of the present embodiments to the full extent indicated by the broad general meaning of the terms in which the appended claims are expressed.

What is claimed is:

1. An electronic device, comprising:
a housing;
a circuit board received in the housing;
a signal receiving unit secured to the circuit board;
a sensor window cover secured to the housing and corresponding to the signal receiving unit; and
at least one limiting post secured to an inner surface of the housing;
wherein the sensor window cover defines at least one limiting hole for receiving the at least one limiting post, the circuit board abuts the sensor detector window to secure the sensor window cover to the housing when the at least one limiting post is received in the at least one limiting hole.

2. The electronic device of claim 1, wherein the sensor window cover comprises a base having a first end and a second end opposite to the first end, and a window arranged between the first and second ends.

3. The electronic device of claim 2, wherein the housing defines an opening corresponding to the signal receiving unit and used for receiving the window.

4. The electronic device of claim 3, wherein the at least one limiting post is arranged at a side of the opening, the at least one limiting hole is defined on the base and is arranged at a side of the window.

5. The electronic device of claim 4, wherein at least one supporting plate is secured to a surface of the base opposite to the window, the circuit board abuts ends of the at least one supporting plate away from the base to secured the sensor window cover to the housing.

6. The electronic device of claim 5, wherein at least one rib is secured to the base and connects with the at least one plate to enhance the stiffness of the at least one supporting plate.

7. The electronic device of claim 2, further comprising a limiting block and a stopping block, wherein the limiting block and the stopping block are arranged opposite sides of the opening.

8. The electronic device of claim 7, wherein longitudinal planes of the limiting block and the stopping block are perpendicular to each other, and the distance between the limiting block and the stopping block is slightly greater than the distance between the first and second ends.

9. The electronic device of claim 8, wherein two protruding blocks are secured to the second end, the protruding blocks are spaced from each other to define a recess.

10. The electronic device of claim 9, wherein the recess is used for receiving the limiting block when the window is received in the opening.

11. The electronic device of claim 10, wherein the distance between the distal end of the protruding blocks and the window is greater than the distance between the stopping block and an edge of the opening adjacent to the stopping block.

12. The electronic device of claim 1, wherein the sensor window cover is made of polymethyl methacrylate.
